(19) United States
(12) Patent Application Publication
(10) Pub. No.: US 2007/0018253 A1
(43) Pub. Date: Jan. 25, 2007

(54) Memory cell and manufacturing methods

(75) Inventor: Jhon-Jhy Liaw, Hsin-Chu (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/202,445

(22) Filed: Aug. 12, 2005

Related U.S. Application Data
(60) Provisional application No. 60/700,957, filed on Jul. 20, 2005.

(51) Int. Cl. H01L 29/76

(52) U.S. Cl. 257/369

(57) ABSTRACT

A semiconductor structure and methods of forming the same are provided. The semiconductor structure includes a semiconductor substrate, a first memory device array on the semiconductor substrate, and a logic circuit on the semiconductor substrate. Substantially all gates of at least one type of PMOS and NMOS devices in the first memory device array and the logic circuit are unidirectional. The pocket regions and lightly doped drain/source regions are therefore tilt implanted at rotation angles substantially close to 0 degrees and 180 degrees.

This application claims priority to provisional patent application Ser. No. 60/700,957, filed Jul. 20, 2005, and entitled “Memory Cell and Manufacturing Methods,” which application is incorporated herein by reference.

### TECHNICAL FIELD

This invention relates generally to semiconductor devices, and more particularly to memory cells, and even more particularly to layout design and manufacturing methods of static random access memory cells.

### BACKGROUND

With the scaling of VLSI circuits, more devices are put into a chip. This not only requires shrinkage of the device size, but it also requires an improvement in the manufacturing techniques. One example is a memory chip. Due to the high capacity requirement of the memory chip, the ability to reduce layout area is especially important. Therefore, the devices in the memory chip are arranged close to each other to save space.

In memory development, layout area, cell stability and standby current are among the most important factors. Therefore, the CMOS static random access memory (SRAM) cell has become the main stream in deep sub-micron technology. FIG. 1 illustrates a circuit diagram of a typical 6T SRAM cell, which includes pass-gate transistors 10 and 24, pull-up transistors 12 and 16, and pull-down transistors 14 and 18. The gate 2 of the pass-gate transistor 10 is controlled by a word-line WL that determines whether the current SRAM cell is selected or not selected. A latch formed of pull-up transistors 12 and 16 and pull-down transistors 14 and 18 stores a state. The stored state can be read through the bit line BL.

To achieve maximum density, the distance between devices, particularly the distance between N-well regions and P-well regions, must be as small as possible. This pushes the layout rules of lightly doped drain (LDD) regions of the MOS devices to their limit.

The high density of the memory chips, however, induces problems. In deep sub-micron SRAM design, due to process variations and pocket implant shadowing effects, cell mismatch issues arise. Typically, pocket implants are performed to improve short channel characteristics. Dopants introduced by pocket implants are preferably located around the LDD dopants with a small portion under the gate. Therefore, rotation implants are generally used in current technology. FIG. 2A illustrates a typical implanting scheme for the formation of pocket regions 34 and 36 of a MOS device 37. Two tilt implants, which are symbolized by arrows 30₁ and 30₂, are performed perpendicular to the length direction of the gate electrode 38, forming pocket regions 34 and 36, respectively. Since, in a typical wafer, features are laid out in two directions X and Y that are perpendicular to each other, some of the gate electrodes are in X direction and others are in Y direction. Accordingly, rotation implants become necessary.

FIG. 2B illustrates a top view of the pocket implantation scheme shown in FIG. 2A, wherein the rotation implants include four implants 30₁, 30₂, 62₁, and 62₂ rotating around the MOS device 37. Arrows 62₁, and 62₂ symbolize pocket implants tilted to X direction, which form pocket regions 39 in FIG. 2A. Since the impurity type in the pocket regions 39 is the same as the impurity in the well region 56 (refer to FIG. 2A) in which the MOS device is formed, the effective concentration in the well region 56 increases due to undesired pocket regions 39, resulting in higher gate induced drain leakage (GIDL) current. Also, the parasitic capacitances between the source/drain regions (including LDD regions) and pocket regions 34, 36 and 39 also increase due to the increased concentration in the pocket regions 39.

Another problem in conventional memory design is the threshold voltage mismatch between the pull-up transistors 12 and 16 and the threshold voltage mismatch between the pull-down transistors 14 and 18 (refer to FIG. 1). A top view of an LDD region implantation scheme is illustrated in FIG. 3, which schematically illustrates the implanting of LDD regions of NMOS devices 14 and 18 (refer to FIG. 1). When LDD implants of NMOS devices 14 and 18 are performed, PMOS device regions are to be protected by a photo resist 64. Since the gates of the NMOS transistors 14 and 18 are in X direction, the LDD regions of the NMOS transistors 14 and 18 are formed by tilt implants 60, which tilt to Y direction. However, there exists other NMOS devices (not shown) having gate electrode length in Y direction on the same chip/wafer, thus LDD implants 62₁ and 62₂, which tilt to the X direction, will also be performed. Due to process variations, the photo resist 64, which is desired to be in the middle of the NMOS transistors 14 and 18, may deviate from the designed position, and photo resist 66 may actually be formed instead of photo resist 64. Since the implants 62₁ and 62₂ are tilted, the photo resist 66 shadows the implanted ions of tilt implants 62₂ for the NMOS device 14 and tilt implants 62₁ for the NMOS device 18. Because the photo resist 66 becomes closer to the NMOS device 18, LDD dopants introduced by tilt implants 62₁ are shadowed more, reducing the threshold voltage of the NMOS transistor 18. Conversely, the threshold voltage of the NMOS transistor 14 is at least not reduced since it has more clearance space from the photo resist 66. As a result, the NMOS devices 14 and 18 have mismatched threshold voltages.

What is needed, therefore, is a method to solve the previously discussed issues, forming memory cell devices having lower junction leakage currents and lower parasitic capacitances.

### SUMMARY OF THE INVENTION

A semiconductor structure including at least a memory array and methods of forming the same using improved implanting schemes are provided.

In accordance with one aspect of the present invention, the semiconductor structure includes a semiconductor substrate, a first memory device array on the semiconductor substrate, and a logic circuit on the semiconductor substrate. Substantially all gates of at least one type of PMOS and NMOS devices in the first memory device array and the logic circuit are unidirectional and in a gate direction. The pocket regions and lightly doped drain/source regions are preferably tilt implanted perpendicular to the gate direction. The logic circuit is the circuit that performs functions other than those performed by memory device arrays and input/output (I/O) circuits. Preferably, the gate dielectric thickness of MOS devices in the logic circuit is less than the gate dielectric thickness of the I/O circuits. The memory device arrays include static random access memory (SRAM) arrays, dynamic random access memory (DRAM) arrays, or other types of memory arrays.

In accordance with another aspect of the present invention, the semiconductor structure further includes a second memory device array wherein substantially all gates of at least one type of PMOS and NMOS devices in the second memory device array are in the gate direction. More memory device arrays may be included in the semiconductor structure wherein substantially all gates of the at least one type of PMOS and NMOS devices in the memory device arrays are in the gate direction.

In accordance with another aspect of the present invention, the device arrays in a memory chip are DRAM arrays, and one or more device arrays, and preferably all device arrays, on a memory chip comprise substantially PMOS devices or NMOS devices only. The PMOS or NMOS devices in the memory device arrays are in the gate direction.

In accordance with yet another aspect of the present invention, a method of forming the preferred embodiments of the present invention includes providing a substrate, forming a gate dielectric layer overlying the substrate and forming a conductive layer thereon, patterning the gate dielectric layer and the conductive layer to form gate structures for a plurality of MOS devices wherein substantially all gates of the MOS devices extend in a gate direction, and performing an ion implantation procedure in a direction substantially perpendicular to the gate direction. The impurity introduced by the ion implantation procedure has a same type as the impurity type of the well regions on which the respective gate structures are formed. The MOS devices may belong to one or more memory device arrays. Furthermore, some of the MOS devices may belong to a logic circuit. In the preferred embodiment, substantially all PMOS and NMOS devices in the memory device arrays and logic circuits have gates in the gate direction. In other embodiments, substantially all PMOS devices in the memory device arrays and logic circuits have gates in the gate direction. In yet other embodiments, substantially all NMOS devices in the memory device arrays and logic circuits have gates in the gate direction.

In accordance with yet another aspect of the present invention, the ion implantation procedure comprises a first implantation process having a rotation angle of about 0 degrees and a second implantation process having a rotation angle of about 180 degrees. The tilt angle is preferably between about 15 and about 75 degrees. Each of the first and second implantation processes may include more than one implantation having different tilt angles.

The preferred embodiments of the present invention have reduced junction leakage currents and reduced parasitic capacitances.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a schematic circuit diagram of a typical six-transistor SRAM;

FIGS. 2A, 2B and 3 illustrate a cross-sectional view and top views of a conventional implantation scheme, respectively;

FIG. 4 illustrates a layout of a six-transistor SRAM in the preferred embodiment of the present invention; and

FIGS. 5 through 10 illustrate intermediate stages in the manufacture of the preferred embodiments of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

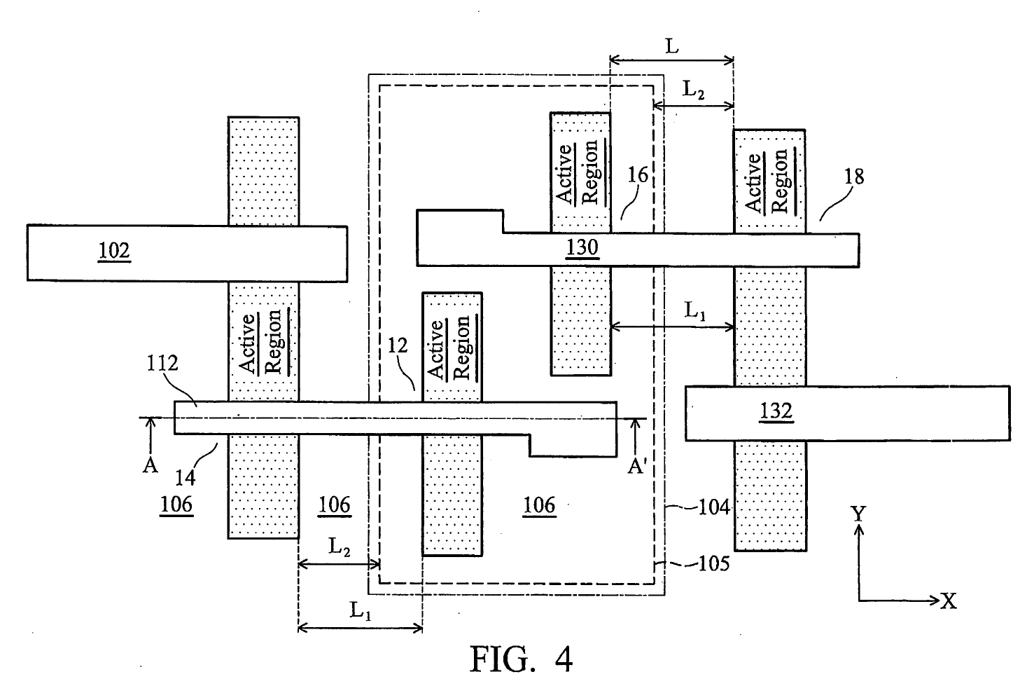

The preferred embodiments of the present invention are illustrated in FIGS. 4 through 10, wherein like reference numbers are used to identify like elements. It is to be appreciated that although the preferred embodiments of the present invention use a 6-T memory cell as an example, the concept of the present invention applies to memory cells with different numbers of transistors. Also, the preferred embodiments of the present invention are preferably used for the fabrication of CMOS static random access memories (SRAM) due to their high density, however, the concept is readily available for the design of dynamic random access memory (DRAM), other types of memories, and any other integrated circuits having high density.

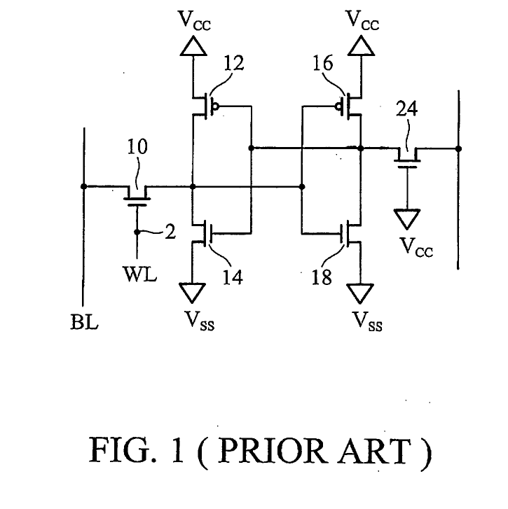

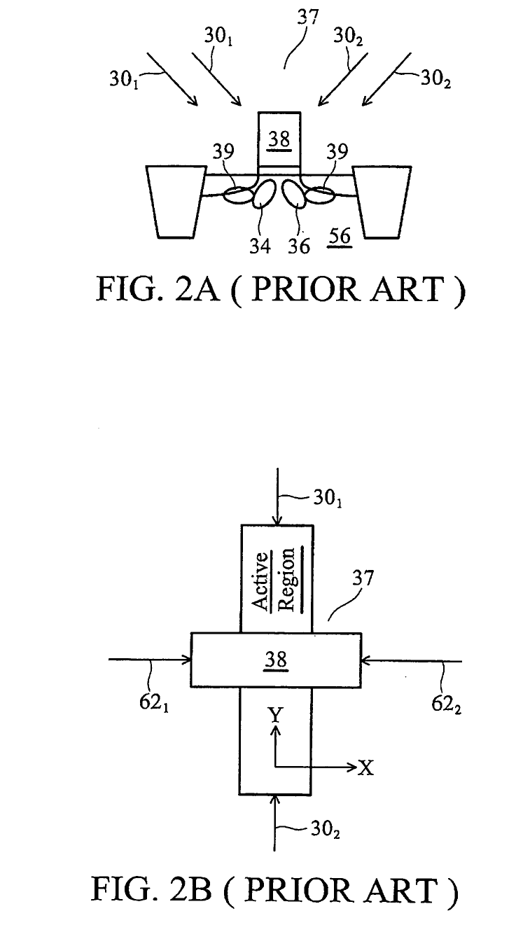

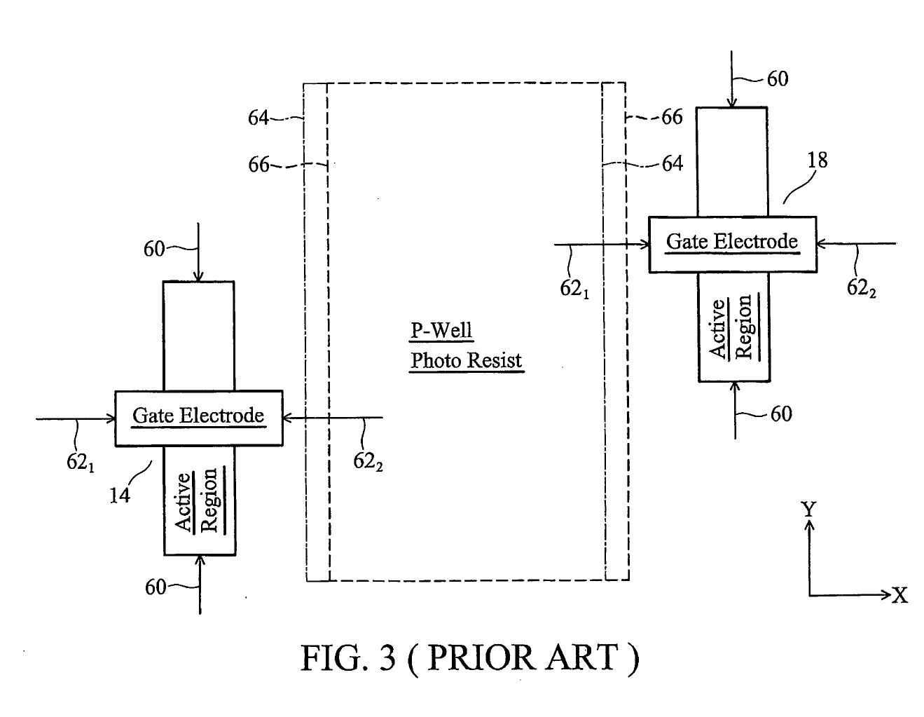

FIG. 4 illustrates a portion of the layout diagram of a six-transistor (6-T) memory cell, which is shown in FIG. 1. For simplicity purposes, vias and metal lines are not shown. There are four gate conductors 102, 112, 130 and 132, sometimes referred to as gate polys if formed of polysilicon. The gate conductors may also be formed of other conductive materials, such as metal, metal silicide, etc. The gate conductors are all in X direction so that the channel lengths of the respective MOS devices 14 and 18 are in Y direction. Shallow trench isolation regions (STI) 106 isolate active regions of the MOS devices. A rectangle 104 indicates the boundary of a photo resist used for protecting the PMOS devices 12 and 16 when the NMOS devices 14 and 18 are fabricated.

The preferred embodiments of the present invention are particularly useful for tightly spaced memory cells. Preferably, the distance L₁ between the active region of a (pull-down) NMOS device and the active region of the nearest (pull-up) PMOS device is preferably less than about 140 nm. Also, the active regions of the NMOS devices 14 and 18 are preferably spaced apart from the N-well 105 by a distance L₂ of less than about 75 nm.

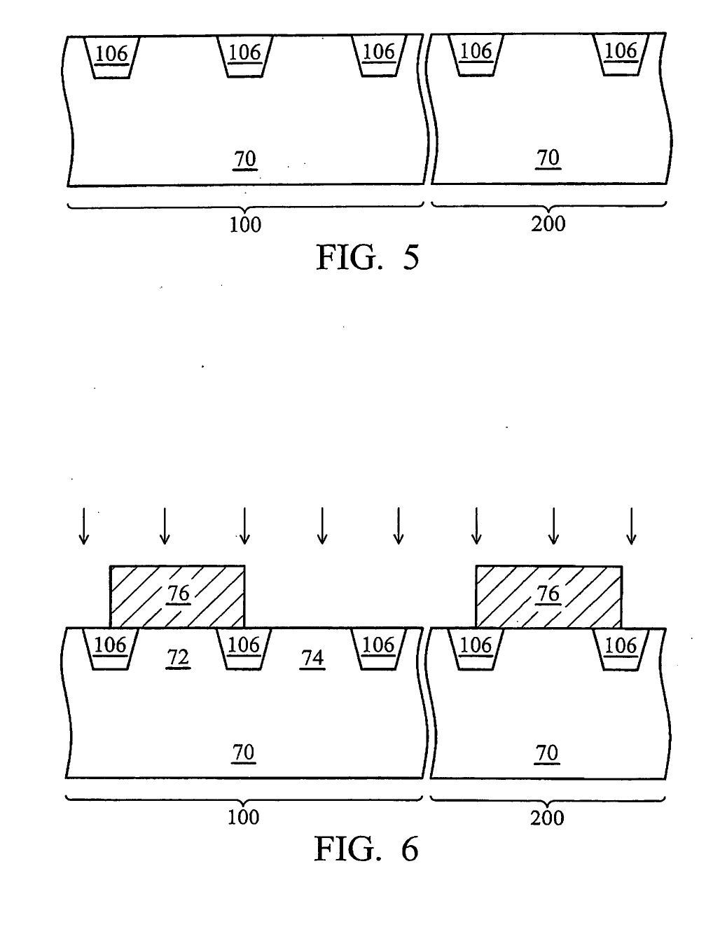

FIGS. 5 through 10 illustrate intermediate stages in the manufacture of the preferred embodiments of the present invention. Referring to FIG. 5, a substrate 70 is provided. The substrate 70 can be formed of common substrate materials such as silicon, SiGe, strained silicon on SiGe, silicon on insulator (SOI), silicon germanium on insulator (SGOI), germanium on insulator (GOI), and the like. The substrate 70 preferably includes device regions 100 and 200, which are used for forming different MOS devices. Region 100 represents a cross-sectional view along line A-A′ in FIG. 4, and is the region for forming the MOS devices of a memory cell. In the preferred embodiment, a MOS device for another memory cell is formed in region 200. In other embodiments, a MOS device for a logic circuit is formed in region 200. In yet other embodiments, a MOS device for an input/output (I/O) circuit is formed in region 200. Throughout the description, a logic circuit is defined as a circuit on the memory chip that does not perform memory or I/O functions, and may include circuits such as a central processing unit (CPU), a graphics processing unit (GPU), a digital signal processing (DSP) unit, a memory sense amplifier (SA) circuit, a decoder circuit, a selector circuit, and the like. MOS devices for I/O circuits typically have thicker gate dielectrics than MOS devices for logic circuits and memory cells. Preferably, the gate dielectric thicknesses of MOS devices in logic circuits are preferably less than about 80 percent of that of the MOS devices in I/O circuits, and more preferably between about 30 percent and about 80 percent. More preferably, the gate dielectric thicknesses of the MOS devices in the logic circuits are substantially the same as that of the MOS devices in the memory cells. For simplicity purposes, the cross-sectional view of regions 100 and 200 are shown as in one plane throughout the description. One skilled in the art will recognize that they can be in different planes.

FIG. 5 also illustrates the formation of STIs 106. Preferably, the STIs 106 are formed by making trenches in the substrate 70, filling the trench with a dielectric material, such as SiO₂ or HDP oxide, and performing a chemical mechanical polish to level the surface, forming the STI regions 106. The STI regions 106 in region 100 divide the substrate into sub regions.

FIG. 6 illustrates the formation of a P-well region 72 and an N-well region 74. A photo resist 76 is formed and patterned using lithography techniques, covering portions of the regions 100 and 200. An N-type impurity implantation is then performed in order to form the N-well region 74. The N-well region 74 preferably comprises antimony and/or arsenic. The photo resist 76 is then removed. Another photo resist (not shown) is used to mask the N-well regions 74. A P-type impurity implantation is performed, forming the P-well region 72. Preferably, P-type impurities such as boron, B₁₁, and/or indium are used.

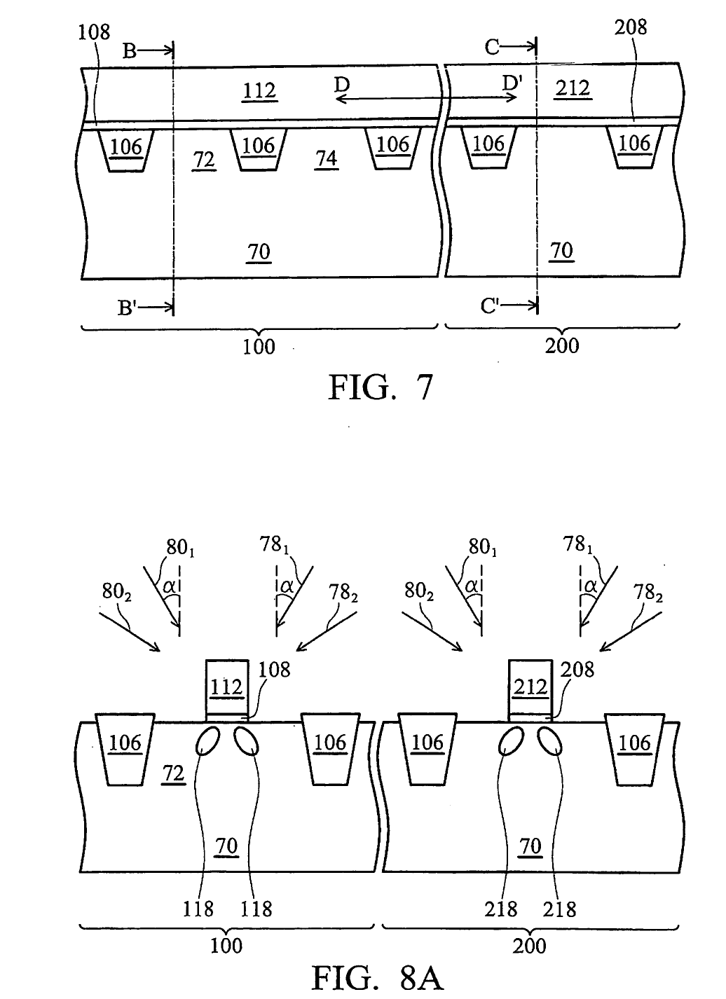

FIG. 7 illustrates the formation of gate dielectrics and gate electrodes. In region 100, a gate dielectric 108 and a gate electrode 112 are formed extending over the P-well region 72 and the N-well region 74, thus connecting the gates of the subsequently formed NMOS and PMOS devices. In region 200, a gate dielectric 208 and a gate electrode 212 are formed. It is preferred that the gate electrodes 112 and 212 are unidirectional. In other words, the gate directions, which are typically known as the channel-width direction of the respective MOS devices, of the gate electrodes 112 and 212 are the same. The gate direction is shown as the direction between points D and D′.

As is known in the art, in order to form the gate dielectrics 108 and 208 and gate electrodes 112 and 212, a gate dielectric layer is blanket formed, followed by the formation of a gate electrode layer. The gate dielectric layer preferably has a high K value. The gate electrode layer preferably comprises polysilicon, metals or metal silicides. The gate dielectric layer and the gate electrode layer are then patterned to form the gate dielectrics 108 and 208 and the gate electrodes 112 and 212, respectively.

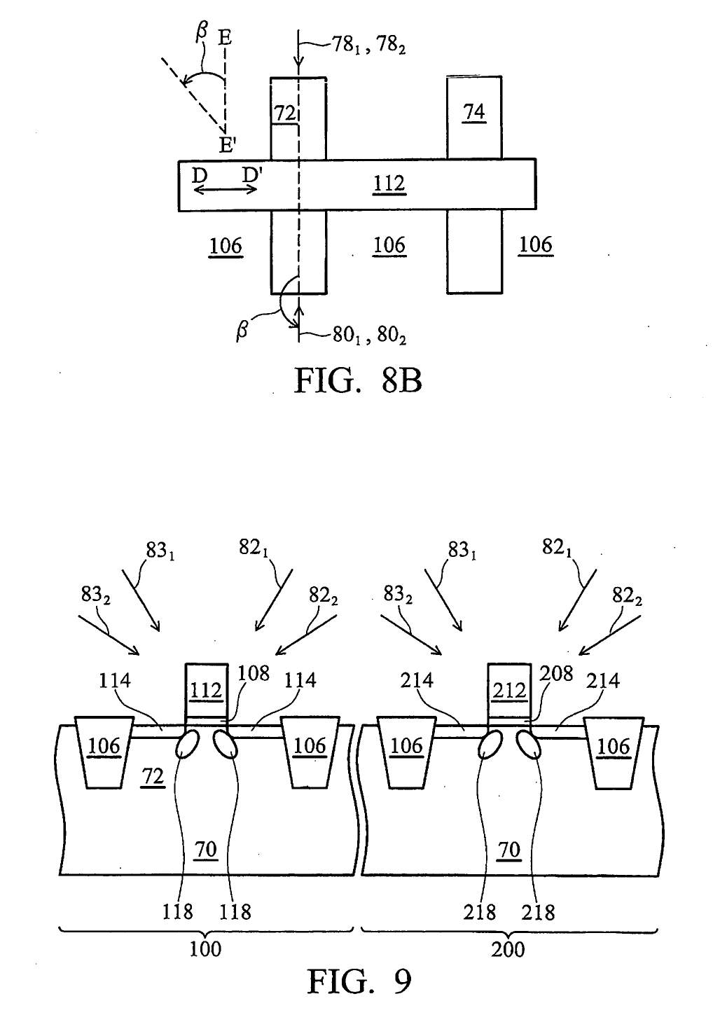

FIGS. 8A through 10 illustrate the formation of NMOS devices in regions 100 and 200, wherein the cross-sectional views of regions 100 and 200 are taken along lines B-B′ and C-C′, respectively.

FIG. 8A illustrates the formation of pocket regions 118. The implanted impurity preferably comprises boron, B₁₁, indium, and combinations thereof. The direction of the tilt implants is defined by a rotation angle and a tilt angle. FIG. 8B illustrates a top view of region 100 in FIG. 8A. If a rotation angle β is defined as an angle rotating from a line E-E′ that is perpendicular to the gate direction D-D′ (in the plane shown in FIG. 8B), then the tilt implants 78₁ and 78₂ preferably have a rotation angle μ of between about −10 and 10 degrees, and more preferably substantially close to 0 degrees, and the tilt implants 80₁ and 80₂ preferably have a rotation angle μ of between about 170 and 190 degrees, and more preferably substantially close to 180 degrees.

Referring back to FIG. 8A, the tilt implants 78₁ and 80₁ form the pocket regions 118. Additional photo resist (not shown) may be needed to limit the pocket regions to close to regions under the side edges of the gate electrode 112. In the preferred embodiment, two tilt implants 78₁ and 80₁ are performed. In other embodiments, four or more implants can be performed, which preferably have different tilt angles α and/or different energy levels. FIG. 8A illustrates additional tilt implants 78₂ and 80₂, although more tilt implants can be performed. Regardless of the number and the tilt angles of the tilt implants, the rotation angle of each of the tilt implants is substantially close to 0 or 180 degrees. Tilt implants 78₁, 78₂, 80₁ and 80₂ preferably have a tilt angle α of between about 15 degrees and about 75 degrees so that the pocket regions 118 extend under the gate electrode 112. At the same time that the pocket regions 118 are formed, the pocket regions 218 are also preferably formed in region 200.

FIG. 9 illustrates the formation of lightly doped drain/source (LDD) regions 114 and 214. The LDD regions 114 are formed by implanting n-type impurities, such as arsenic and/or phosphorus. Arrows 82₁ and 83₁ symbolize tilt implants, which are preferably performed at a tilt angle of between about 0 degrees and 7 degrees. However, the LDD implantation may be performed vertically. At the same time the LDD regions 114 are formed, the LDD regions 214 are preferably formed in regions 200. Similar to the formation of the pocket regions, if the LDD regions 114 and 214 are tilt implanted, two or more implants can be performed, as shown by additional implants 82₂ and 83₂, and tilt angles for each tilt implantation may be different. However, the rotation angle of each implantation is preferably substantially close to 0 degrees or about 180 degrees.

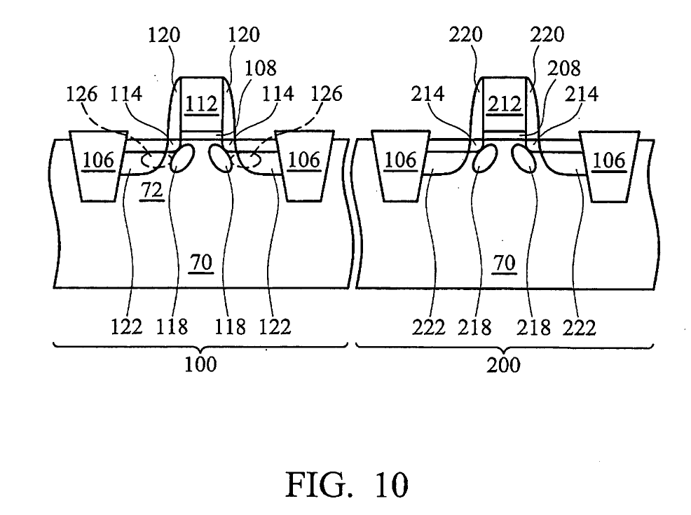

FIG. 10 illustrates the formation of spacers 120, 220 and heavily doped source/drain (N+S/D) regions 122 and 222. The spacers 120 and 220 are formed along the sidewalls of the gate electrodes 112 and 212, respectively. As is known in the art, the gate spacers 120 and 220 are preferably formed by blanket depositing a dielectric layer over an entire region, then anisotropically etching to remove the dielectric layer from horizontal surfaces, and thus leaving the gate spacers 120 and 220. The spacers 120 and 220 are preferably used as masks for the formation of the N+S/D regions 122 and 222, respectively. N-type impurities, such as arsenic and/or phosphorus, are preferably implanted.

Although in previously discussed steps, only the formation of NMOS devices is described, one skilled in the art will realize the fabrication steps of PMOS devices. During certain steps for forming the NMOS devices, the PMOS regions are preferably masked. Conversely, during certain steps for forming the PMOS devices, the NMOS regions are preferably masked.

In the preferred embodiment, substantially all NMOS devices in regions 100 and 200 have unidirectional gates, and substantially all PMOS devices in regions 100 and 200 have unidirectional gates. In other embodiments, substantially all NMOS devices in regions 100 and 200 have unidirectional gates, while PMOS devices may have different gate directions. In yet other embodiments, substantially all PMOS devices in regions 100 and 200 have unidirectional gates, while NMOS devices may have different gate directions. In yet other embodiments, a memory chip comprises more than one memory device array, and more preferably at least five memory device arrays, and substantially all of the NMOS devices, PMOS devices, or NMOS and PMOS devices in the memory device arrays have unidirectional gates. In further embodiments, one or more device arrays, and preferably all device arrays, on a memory chip comprise substantially PMOS devices or NMOS devices only, so that the fabrication processes are simplified. Particularly, DRAM arrays may formed with substantially one type of MOS devices.

The preferred embodiments of the present invention have significantly improved leakage currents. Compared to prior art devices having pocket regions formed by implants with four rotation angles, extra pocket regions that will be otherwise formed in the regions 126 are not formed. As a result, the gate induced drain leakage (GIDL) current of the MOS device is reduced. Experiment results have revealed that the junction leakages in the pass-gate NMOS devices 10 and 24 (refer to FIG. 1) are reduced by over 90 percent. For pull-down NMOS devices 14 and 18, the junction leakage currents of the preferred embodiments of the present invention are also reduced by over 85 percent.

Since in the preferred embodiments of the present invention, tilt implants for pocket regions and LDD regions are performed only from two rotation angles, the variation of the photo resist 64 (refer to FIG. 4) does not affect the dopant concentrations, and better device matching and better cell performance can be achieved.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a semiconductor substrate;
a first memory device array on the semiconductor substrate;
a logic circuit on the semiconductor substrate;
wherein substantially all gates of at least one type of PMOS devices and NMOS devices in the first memory device array and the logic circuit are in a gate direction; and
wherein gate dielectrics of the MOS devices in the memory device array have substantially a same thickness as gate dielectrics of the MOS devices in the logic circuit.

2. The semiconductor device of claim 1 further comprising a second memory device array wherein substantially all gates of at least one type of the PMOS devices and the NMOS devices in the second memory device array are in the gate direction.

3. The semiconductor device of claim 1 further comprising at least four memory device arrays wherein substantially all gates of at least one type of the PMOS devices and the NMOS devices in the at least four memory device arrays are in the gate direction.

4. The semiconductor device of claim 1 further comprising an input/output circuit on the substrate having a gate dielectric thickness substantially different from the thickness of the gate dielectrics in the first memory device array, wherein substantially all gates of at least one type of the PMOS devices and NMOS devices in the input/output circuit are in the gate direction.

5. The semiconductor device of claim 1 wherein pocket regions of transistors in the first memory device array and transistors in the logic circuit are formed by ion implantations each having a rotation angle substantially close to 0 degrees or 180 degrees.

6. The semiconductor device of claim 1 wherein lightly doped source/drain (LDD) regions of transistors in the first memory device array and transistors in the logic circuit are formed by ion implantations each having a rotation angle substantially close to 0 degrees or 180 degrees.

7. The semiconductor device of claim 1 wherein the at least one type of the PMOS devices and the NMOS devices in the first memory device array and the logic circuit are NMOS transistors.

8. The semiconductor device of claim 1 wherein the first memory device array comprises a dynamic random access memory (DRAM) device array, and wherein the first memory device array comprises substantially one type of MOS devices.

9. The semiconductor device of claim 1 wherein the first memory device array comprises a static random access memory (SRAM) device array.

10. The semiconductor device of claim 1 wherein the first memory device array comprises a pull-down device and a pull-up device, and wherein an active region of the pull-down device and an active region of the pull-up device are spaced apart by a distance of less than about 140 nm.

11. A chip comprising the semiconductor device of claim 1.

12. A semiconductor device comprising:
a substrate;
at least two device arrays comprising transistors having substantially all gates laid out in a gate direction;
wherein each of the transistors comprises pocket regions formed by ion implantation procedures tilted in a direction substantially perpendicular to the gate direction; and
wherein each of the transistors is formed in a well region, and wherein the pocket regions of each of the transistors has a same conductivity type as the respective well region.

13. The semiconductor device of claim 12 wherein the transistors in the at least two device arrays are NMOS transistors.

14. The semiconductor device of claim 12 wherein the transistors in the at least two device arrays are PMOS transistors.

15. The semiconductor device of claim 12 wherein the ion implantation procedures comprise more than two implantation processes each having a tilt angle of between about 15 and 70 degrees.

16. The semiconductor device of claim 12 wherein the at least two device arrays comprise memory cell arrays.

17. The semiconductor device of claim 16 wherein the memory cell arrays comprise SRAM cell arrays.

18. The semiconductor device of claim 12 further comprising a logic circuit, wherein substantially all gates of transistors in the logic circuit are in an additional gate direction.

19. The semiconductor device of claim 18 wherein the additional gate direction is parallel to the gate direction.

20. The semiconductor device of claim 18 wherein the additional gate direction is perpendicular to the gate direction.
